(19) United States
(12) Patent Application Publication
(10) Pub. No.: US 2026/0305354 A1
(43) Pub. Date: Oct. 1, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Ryota SAKANISHI, Oita Oita (JP); Hiroshi SASAKI, Hanamaki Iwate (JP); Yoshiaki ISHII, Oita Oita (JP); Yusuke AKASHI, Yokohama Kanagawa (JP)

(21) Appl. No.: 19/365,809

(22) Filed: Oct. 22, 2025

(30) Foreign Application Priority Data
Mar. 25, 2025 (JP) 2025-049266

(51) Int. Cl. H10W 42/00

(52) U.S. Cl. CPC H10W 42/121

(57) ABSTRACT

A semiconductor device according to an embodiment includes: an element region; and a peripheral region surrounding the element region, in which the element region and the peripheral region include a semiconductor layer having a first face parallel to a first direction and a second direction, orthogonal to the first direction, and a second face opposite to the first face, the semiconductor layer in the peripheral region includes a plurality of trenches regularly disposed on the first face, and the plurality of trenches include a first trench having a first major axis and a first minor axis and extending in the first direction, and a second trench adjacent to the first trench in the second direction, the second trench having a second major axis and a second minor axis and extending in a third direction parallel to the first face, the third direction intersecting the first direction.

### CROSS-REFERENCE TO RELATED APPLICATION

This application is based upon and claims the benefit of priority from Japanese Patent Application No. 2025-049266, filed on Mar. 25, 2025, the entire contents of which are incorporated herein by reference.

### FIELD

Embodiments described herein relate generally to a semiconductor device.

### BACKGROUND

A semiconductor device is manufactured by performing various processes such as formation of a film on a semiconductor wafer, etching of the formed film, and heat treatment. For example, the semiconductor wafer is sometimes warped due to stress or the like of the film formed on the semiconductor wafer. When the semiconductor wafer is warped, for example, a conveyance error occurs in a semiconductor manufacturing apparatus, and there is a possibility that manufacturing of the semiconductor device becomes difficult.

### BRIEF DESCRIPTION OF THE DRAWINGS

FIG. 1 is a schematic top view of a semiconductor device according to a first embodiment;

FIG. 2 is an enlarged schematic top view of the semiconductor device according to the first embodiment;

FIG. 3 is an enlarged schematic cross-sectional view of the semiconductor device according to the first embodiment;

FIG. 4 is an enlarged schematic top view of a semiconductor device according to a comparative example;

FIG. 5 is an explanatory view of a function and an effect of the semiconductor device according to the first embodiment;

FIG. 6 is an explanatory view of the function and effect of the semiconductor device according to the first embodiment;

FIG. 7 is an explanatory view of the function and the effect of the semiconductor device according to the first embodiment;

FIG. 8 is an explanatory view of the function and the effect of the semiconductor device according to the first embodiment;

FIG. 9 is an enlarged schematic top view of a semiconductor device according to a first modification of the first embodiment;

FIG. 10 is an enlarged schematic top view of a semiconductor device according to a second modification of the first embodiment;

FIG. 11 is an enlarged schematic top view of a semiconductor device according to a second embodiment; and

FIG. 12 is an enlarged schematic top view of a semiconductor device according to a third embodiment.

### DETAILED DESCRIPTION

A semiconductor device according to one aspect of the present disclosure includes: an element region; and a peripheral region surrounding the element region, in which the element region and the peripheral region include a semiconductor layer having a first face parallel to a first direction and a second direction, the second direction being orthogonal to the first direction, and a second face opposite to the first face, the semiconductor layer in the peripheral region includes a plurality of trenches regularly disposed on the first face, and the plurality of trenches include a first trench having a first major axis and a first minor axis and extending in the first direction, and a second trench adjacent to the first trench in the second direction, the second trench having a second major axis and a second minor axis and extending in a third direction parallel to the first face, the third direction intersecting the first direction.

In the present specification, the same or similar members will be denoted by the same reference numerals, and redundant descriptions thereof will be omitted in some cases.

In the present specification, the upward direction of the drawing will be described as “upper” and the downward direction of the drawing will be described as “lower” in some cases in order to indicate a positional relation among parts and the like. In the present specification, the concepts of “upper” and “lower” are not necessarily terms indicating a relation with respect to the direction of gravity.

Qualitative analysis and quantitative analysis of chemical compositions of the members forming the semiconductor device in the present specification can be carried out by SIMS and energy dispersive X-ray spectroscopy (EDX). In addition, for example, a scanning electron microscope (SEM) or a transmission electron microscope (TEM) can be used to measure a thickness of the member constituting the semiconductor device, a distance between the members, and the like. In addition, for example, X-ray diffraction (XRD), electron beam diffraction (EBD), or X-ray photoelectron spectroscopy (XPS) can be used to identify a substance of the member constituting the semiconductor device.

### First Embodiment

A semiconductor device according to a first embodiment includes an element region and a peripheral region surrounding the element region. The element region and the peripheral region include a semiconductor layer having a first face parallel to a first direction and a second direction orthogonal to the first direction, and a second face opposite to the first face. The semiconductor layer in the peripheral region includes a plurality of trenches regularly disposed on the first face. The plurality of trenches include a first trench having a first major axis and a first minor axis and extending in the first direction, and a second trench adjacent to the first trench in the second direction, the second trench having a second major axis and a second minor axis and extending in a third direction which is parallel to the first face and intersects the first direction.

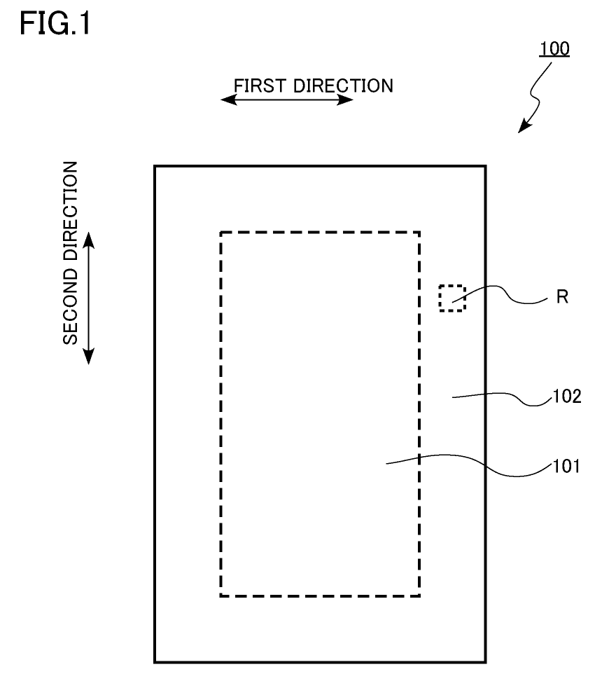

FIG. 1 is a schematic top view of the semiconductor device according to the first embodiment. The semiconductor device according to the first embodiment is a semiconductor device 100. A type of the semiconductor device 100 is not particularly limited. The semiconductor device 100 is, for example, a semiconductor logic device, a semiconductor power device, or a semiconductor memory device.

As illustrated in FIG. 1, the semiconductor device 100 includes an element region 101 and a peripheral region 102. The peripheral region 102 surrounds the element region 101.

The left-right direction in FIG. 1 is a first direction. The up-down direction in FIG. 1 is a second direction. The second direction is orthogonal to the first direction.

In the element region 101, for example, a semiconductor element such as a transistor, a diode, or a capacitor is formed using a semiconductor layer 10. In the element region 101, for example, a semiconductor circuit using the semiconductor element is formed.

In the peripheral region 102, the semiconductor circuit using the semiconductor element is not formed. In the peripheral region 102, for example, an electrode pad (not illustrated) for inputting an electric signal to the semiconductor circuit of the element region 101 and outputting an electric signal from the semiconductor circuit is provided. In addition, in the peripheral region 102, for example, a wiring layer for electrically connecting the semiconductor circuit of the element region 101 and the electrode pad is provided.

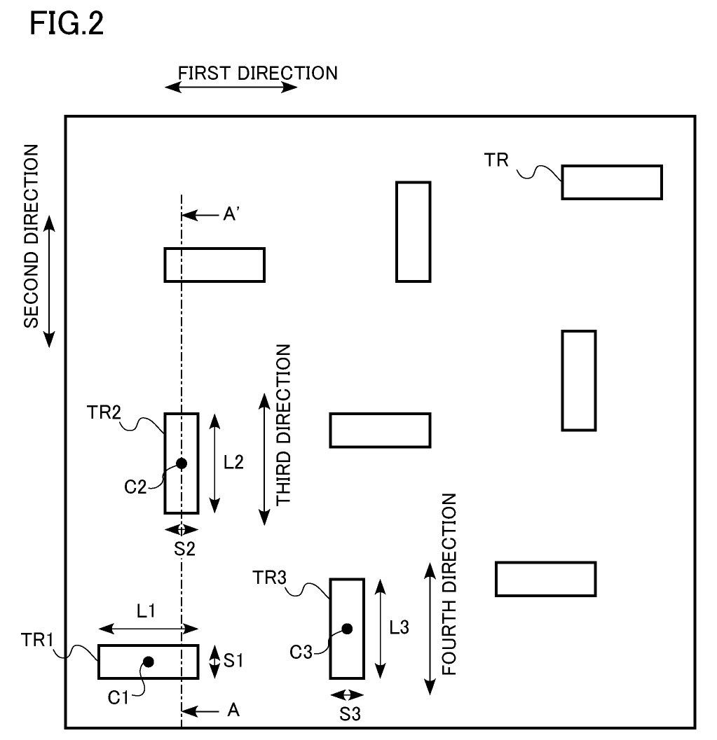

FIG. 2 is an enlarged schematic top view of the semiconductor device according to the first embodiment. FIG. 2 is a top view of a region R that is a part of the peripheral region 102 illustrated in FIG. 1. FIG. 2 is a view illustrating a layout pattern on a surface of the semiconductor layer 10 included in semiconductor device 100.

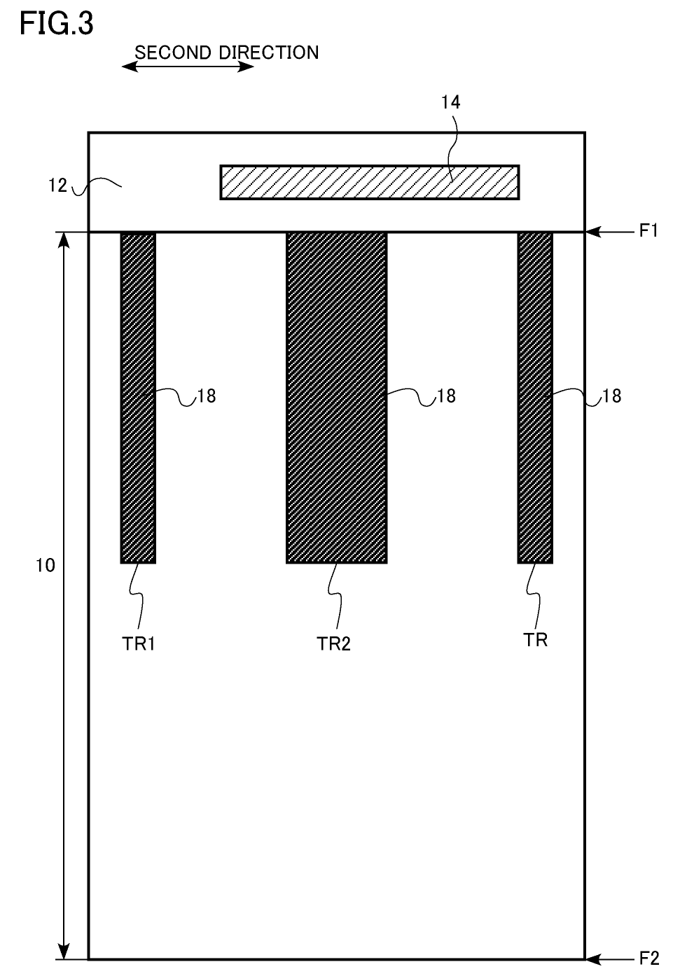

FIG. 3 is an enlarged schematic cross-sectional view of the semiconductor device according to the first embodiment. FIG. 3 is a cross section taken along a line AA' of FIG. 2.

The semiconductor device 100 includes the semiconductor layer 10, an interlayer insulating layer 12, a metal layer 14, and an insulator 18 (first substance). The semiconductor layer 10 includes a plurality of trenches TR. The plurality of trenches TR include a first trench TR1, a second trench TR2, and a third trench TR3.

As illustrated in FIG. 3, the semiconductor layer 10 includes a first face F1 and a second face F2. Hereinafter, the first face F1 and the second face F2 will be referred to as a surface and a back surface, respectively, in some cases. The first face F1 is parallel to the first direction and the second direction.

The semiconductor layer 10 is, for example, silicon. The semiconductor layer 10 is, for example, a single crystal silicon layer.

Each of the element region 101 and the peripheral region 102 includes the semiconductor layer 10.

The semiconductor layer 10 in the peripheral region 102 includes a plurality of trenches TR. The plurality of trenches TR are provided on the first face F1 of the semiconductor layer 10. The plurality of trenches TR are grooves provided in the semiconductor layer 10. Each of the plurality of trenches TR is a part of the semiconductor layer 10.

As illustrated in FIG. 2, the plurality of trenches TR are regularly disposed on the first face F1 of the semiconductor layer 10.

As illustrated in FIG. 2, the first trench TR1 has a first major axis L1 and a first minor axis S1. The first trench TR1 extends in the first direction.

The second trench TR2 is adjacent to the first trench TR1 in the second direction. The second trench TR2 has a second major axis L2 and a second minor axis S2. The second trench TR2 extends in a third direction which is parallel to the first face F1 and intersects the first direction.

In the semiconductor device 100 according to the first embodiment, the second major axis L2 is equal to the first major axis L1. The second minor axis S2 is equal to the first minor axis S1. The third direction coincides with the second direction.

The second major axis L2 and the first major axis L1 can also have different lengths. The second minor axis S2 and the first minor axis S1 can also have different lengths.

A second center position (C2 in FIG. 2) of the second trench TR2 in the first direction is shifted in the first direction with respect to a first center position (C1 in FIG. 2) of the first trench TR1 in the first direction.

The third trench TR3 is adjacent to the first trench TR1 in the first direction. The third trench TR3 has a third major axis L3 and a third minor axis S3. The third trench TR3 extends in a fourth direction which is parallel to the first face F1 and intersects the first direction.

In the semiconductor device 100 according to the first embodiment, the third major axis L3 is equal to the first major axis L1. In addition, the third minor axis S3 is equal to the first minor axis S1. The fourth direction coincides with the second direction.

The third major axis L3 and the first major axis L1 may have different lengths. The third minor axis S3 and the first minor axis S1 may have different lengths.

A third center position (C3 in FIG. 2) of the third trench TR3 in the second direction is shifted in the second direction with respect to the first center position (C1 in FIG. 2) of the first trench TR1 in the second direction.

The first major axis L1, the second major axis L2, and the third major axis L3 are, for example, equal to or more than 2 μm and equal to or less than 10 μm. The first minor axis S1, the second minor axis S2, and the third minor axis S3 are, for example, equal to or more than 0.5 μm and equal to or less than 2.5 μm.

A ratio (L1/S1) of the first major axis L1 to the first minor axis S1, a ratio (L2/S2) of the second major axis L2 to the second minor axis S2, and a ratio (L3/S3) of the third major axis L3 to the third minor axis S3 are, for example, equal to or more than 2 and equal to or less than 20.

In the semiconductor device 100 according to the first embodiment, the trenches TR in two patterns extending in different directions are regularly disposed alternately in the first direction and the second direction on the first face F1.

As illustrated in FIG. 3, the inside of each of the plurality of trenches TR is filled with, for example, the insulator 18. The insulator 18 is an example of a first substance that fills the inside of each of the plurality of trenches TR.

The inside of each of the first trench TR1 and the second trench TR2 is filled with, for example, the insulator 18. The insulator 18 is, for example, an oxide, a nitride, or an oxynitride. The insulator 18 includes, for example, silicon oxide, silicon nitride, or silicon oxynitride. The insulator 18 is, for example, silicon oxide, silicon nitride, or silicon oxynitride.

At least a part of the first substance that fills the inside of each of the first trench TR1 and the second trench TR2 may be, for example, a semiconductor or a conductor. The first substance includes, for example, polycrystalline silicon.

A depth of the first trench TR1 and a depth of the second trench TR2 are, for example, equal to or more than 5 μm and equal to or less than 30 μm.

The depth of the first trench TR1 is, for example, equal to or more than 5 times and equal to or less than 30 times the first minor axis S1. The depth of the first trench TR1 is, for example, equal to or more than 10 times the first minor axis S1. The depth of the second trench TR2 is, for example, equal to or more than 5 times and equal to or less than 30 times the second minor axis S2. The depth of the second trench TR2 is, for example, equal to or more than 10 times the second minor axis S2.

In the present specification, the “depth” means a distance from the first face F1 in a direction from the first face F1 to the second face F2.

The interlayer insulating layer 12 is provided on the semiconductor layer 10. The interlayer insulating layer 12 is an insulator. The interlayer insulating layer 12 is, for example, silicon oxide.

The metal layer 14 is provided in the interlayer insulating layer 12. The metal layer 14 is metal. The metal layer 14 is, for example, a wiring layer for electrically connecting the semiconductor circuit of the element region 101 and the electrode pad.

For example, an element isolation trench (not illustrated) is provided on the first face F1 of the semiconductor layer 10 of the element region 101. The element isolation trench has, for example, a function of performing electrical isolation between the semiconductor elements formed in the element region 101.

The element isolation trench is formed simultaneously with, for example, a plurality of trenches in the peripheral region 102 by the same manufacturing process. The element isolation trench is filled with, for example, the same insulator as that of the plurality of trenches TR in the peripheral region 102.

The plurality of trenches TR in the peripheral region 102 are dummy patterns. When the element isolation trench of the element region 101 is formed, the element isolation trench is filled with an insulator.

For example, the semiconductor layer 10 of the element region 101 is etched to form the element isolation trench. Thereafter, an insulator film is formed inside the element isolation trench and on the surface of the semiconductor layer 10. For example, the inside of the element isolation trench is filled with the insulator by removing the insulator film on the surface of the semiconductor layer 10 by chemical mechanical polishing (CMP).

In a case where a trench pattern is not provided in the peripheral region 102 when the insulator film on the surface of the semiconductor layer 10 is removed by CMP, a density difference of the trench pattern occurs on the surface of the semiconductor layer 10. When the density difference of the trench pattern on the surface of the semiconductor layer 10 is large, in-plane uniformity of removal of the insulator film by CMP is degraded, which causes a problem.

When the dummy pattern of the trench is provided in the peripheral region 102, the density difference of the trench pattern on the surface of the semiconductor layer 10 is reduced, and in-plane uniformity of removal of the insulator film by CMP is improved.

Next, a function and an effect of the semiconductor device according to the first embodiment will be described.

The semiconductor device is manufactured by performing various processes such as formation of a film on a semiconductor wafer, etching of the formed film, and heat treatment. For example, the semiconductor wafer is sometimes warped due to stress or the like of the film formed on the semiconductor wafer. When the semiconductor wafer is warped, for example, a conveyance error occurs in a semiconductor manufacturing apparatus, and there is a possibility that manufacturing of the semiconductor device becomes difficult.

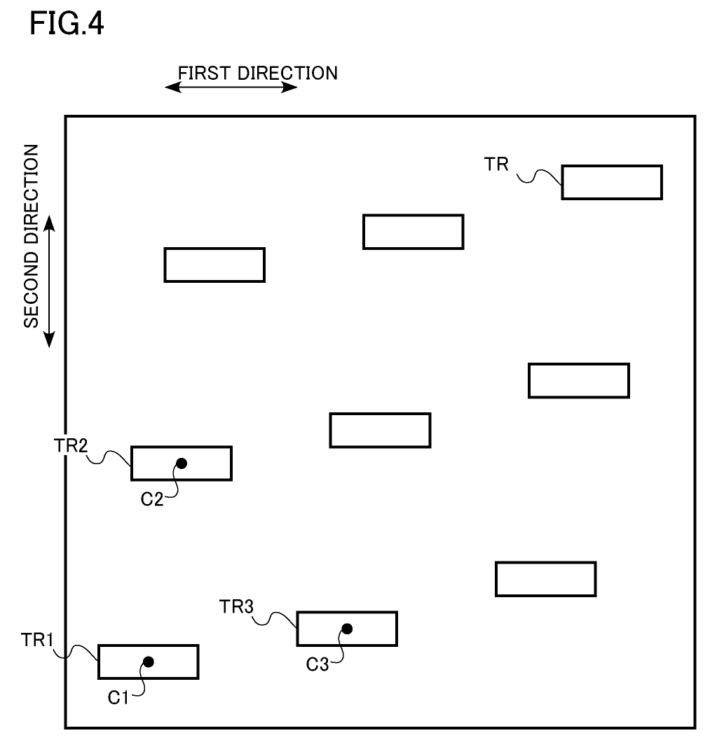

FIG. 4 is an enlarged schematic top view of a semiconductor device according to a comparative example. FIG. 4 is a view corresponding to FIG. 2 of the first embodiment. FIG. 4 is a view illustrating a layout pattern of a surface of semiconductor layer 10 included in the semiconductor device according to the comparative example.

As illustrated in FIG. 4, in the semiconductor device according to the comparative example, similarly to the semiconductor device 100 according to the first embodiment, the plurality of trenches TR are regularly disposed on the first face F1 of the semiconductor layer 10 in the peripheral region 102.

As illustrated in FIG. 4, the first trench TR1 extends in a first direction. The second trench TR2, adjacent to the first trench TR1 in a second direction, extends in the first direction. The third trench TR3, adjacent to the first trench TR1 in the first direction, extends in the first direction.

The semiconductor device according to the comparative example is different from the semiconductor device according to the first embodiment in that all the trenches TR extend in the first direction.

Note that a second center position (C2 in FIG. 4) of the second trench TR2 in the first direction is shifted in the first direction with respect to a first center position (C1 in FIG. 4) of the first trench TR1 in the first direction. In addition, a third center position (C3 in FIG. 4) of the third trench TR3 in the second direction is shifted in the second direction with respect to the first center position (C1 in FIG. 4) of the first trench TR1 in the second direction.

By shifting the center positions of the adjacent trenches TR in the first direction and the second direction, it is possible to prevent misdetection of alignment when a trench pattern is used as an alignment mark of lithography.

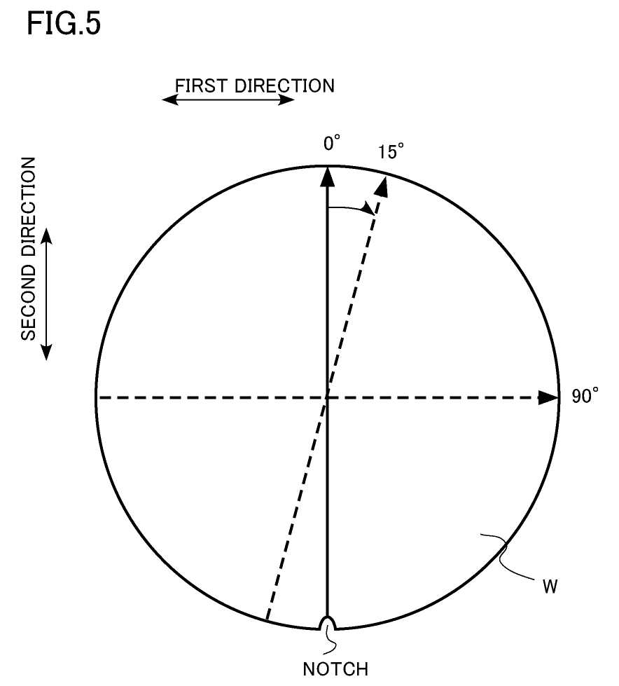

FIGS. 5, 6, 7, and 8 are explanatory views of the function and the effect of the semiconductor device according to the first embodiment.

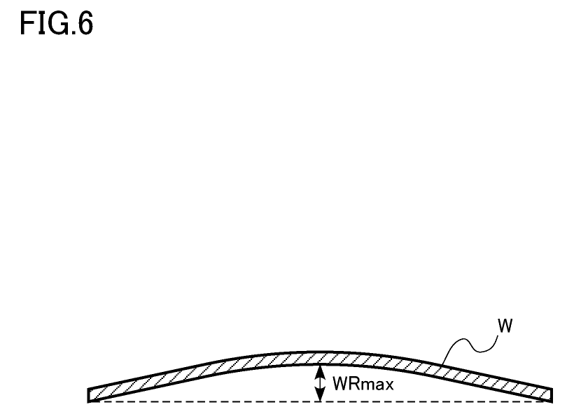

FIGS. 5 and 6 are explanatory views of a method for evaluating the amount of warpage of the semiconductor wafer.

As illustrated in FIG. 5, a direction of a notch of a semiconductor wafer W was set to 0°, and the amount of warpage in a diameter direction of the semiconductor wafer W was evaluated at intervals of 15° clockwise. FIG. 6 illustrates a cross section of the semiconductor wafer W in the diameter direction. As illustrated in FIG. 6, the maximum value (WRmax in FIG. 6) of the amount of warpage of the semiconductor wafer W at each measurement angle was calculated.

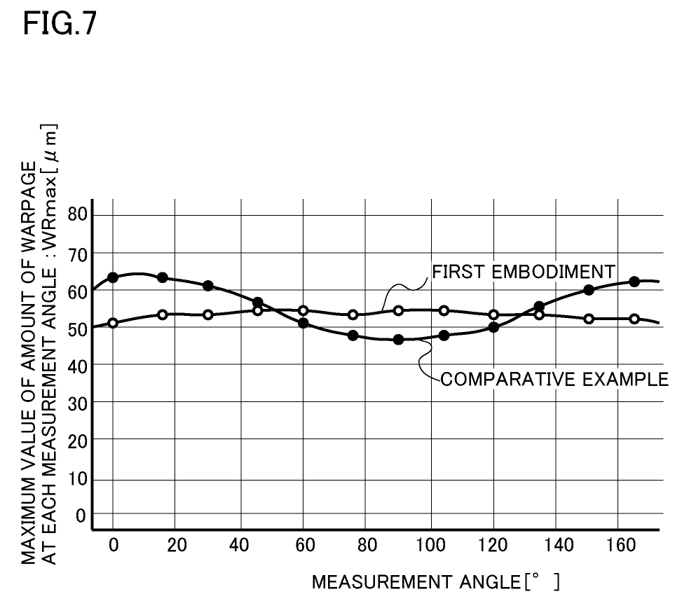

The evaluation was performed on the semiconductor wafer W on which the semiconductor device according to the comparative example was formed and the semiconductor wafer W on which the semiconductor device 100 according to the first embodiment was formed. The results are illustrated in FIG. 7.

As illustrated in FIG. 7, in the semiconductor wafer W of the comparative example, the amount of warpage of the semiconductor wafer W is larger than that of the semiconductor wafer W of the first embodiment. Further, in the semiconductor wafer W of the comparative example, the angle dependence of the amount of warpage of the semiconductor wafer W is larger than that of the semiconductor wafer W of the first embodiment.

In the semiconductor wafer W of the comparative example, the amount of warpage is maximized near a measurement angle of 0°, and the amount of warpage is minimized near a measurement angle of 90°. In the semiconductor wafer W of the first embodiment, a clear angle dependence of the amount of warpage is not recognized.

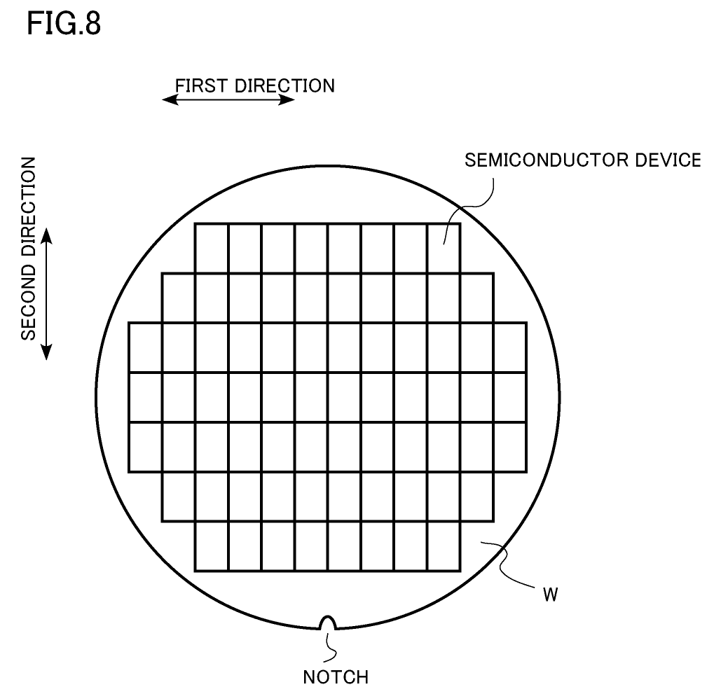

FIG. 8 is a view in the middle of manufacturing the semiconductor device. FIG. 8 illustrates a state in which a plurality of the semiconductor devices are formed on the semiconductor wafer W.

For example, in the semiconductor wafer W on which the semiconductor devices according to the comparative example are formed, extending directions of all the trenches TR in the peripheral region 102 are the first direction in each of the semiconductor devices. Therefore, the extending directions of all the trenches TR are the first direction even when the entire semiconductor wafer W is viewed.

For example, a difference in thermal expansion coefficient between the insulator 18 filling the trench TR and the semiconductor layer 10 generates stress in the semiconductor wafer W, and the semiconductor wafer W is warped. It is considered that the direction dependence of the stress distribution in the semiconductor wafer W becomes apparent and the angle dependence of the amount of warpage of the semiconductor wafer W increases as the extending directions of all the trenches TR become constant.

On the other hand, in the semiconductor wafer W on which the semiconductor devices 100 according to the first embodiment are formed, extending directions of the trenches TR in the peripheral region 102 are two directions of the first direction and the second direction in each of the semiconductor devices 100. For this reason, since the extending directions of the trenches TR are two directions of the first direction and the second direction even when the entire semiconductor wafer W is viewed, it is considered that the direction dependence of the stress distribution in the semiconductor wafer W hardly occurs, and the angle dependence of the amount of warpage of the semiconductor wafer W decreases.

As described above, when the semiconductor wafer W is warped, for example, the conveyance error occurs in the semiconductor manufacturing apparatus, and there is a possibility that manufacturing of the semiconductor device becomes difficult. If the angle dependence of the amount of warpage of the semiconductor wafer W increases, the conveyance error is more likely to occur in the semiconductor manufacturing apparatus. In addition, if the angle dependence of the amount of warpage of the semiconductor wafer W increases, in-plane variation in a semiconductor manufacturing process increases so that there is a possibility that characteristic variation in the semiconductor device increases.

In the semiconductor device according to the first embodiment, it is possible to reduce the amount of warpage of the semiconductor wafer W and to reduce the angle dependence of the amount of warpage of the semiconductor wafer W.

### First Modification

A semiconductor device according to a first modification of the first embodiment is different from the semiconductor device according to the first embodiment in that shapes of a plurality of trenches are different.

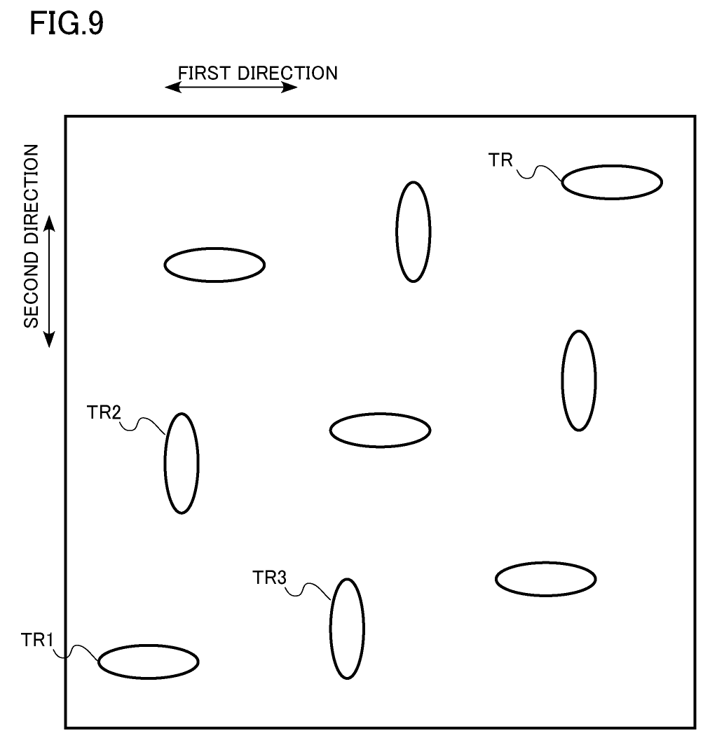

FIG. 9 is an enlarged schematic top view of the semiconductor device according to the first modification of the first embodiment. FIG. 9 is a view corresponding to FIG. 2 of the first embodiment.

Each of the plurality of trenches TR of the first modification of the first embodiment has an elliptical shape.

In the semiconductor device according to the first modification of the first embodiment, it is possible to reduce the amount of warpage of the semiconductor wafer W and to reduce the angle dependence of the amount of warpage of the semiconductor wafer W.

### Second Modification

A semiconductor device according to a second modification of the first embodiment is different from the semiconductor device according to the first embodiment in that shapes of a plurality of trenches are different.

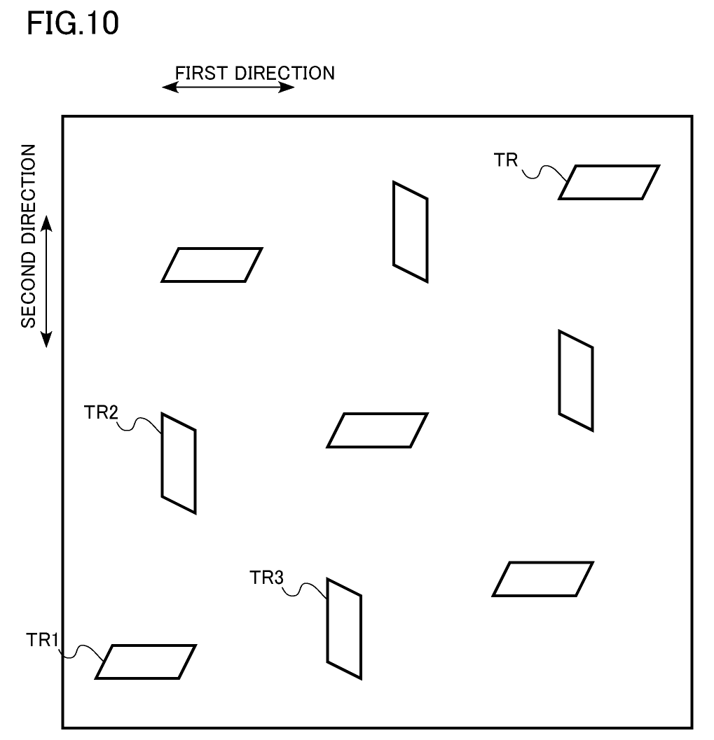

FIG. 10 is an enlarged schematic top view of the semiconductor device according to the second modification of the first embodiment. FIG. 10 is a view corresponding to FIG. 2 of the first embodiment.

Each of the plurality of trenches TR of the second modification of the first embodiment has a parallelogram shape.

In the semiconductor device according to the second modification of the first embodiment, it is possible to reduce the amount of warpage of the semiconductor wafer W and to reduce the angle dependence of the amount of warpage of the semiconductor wafer W.

As described above, according to the first embodiment and the modifications, it is possible to achieve the semiconductor device capable of suppressing the warpage of the semiconductor wafer.

### Second Embodiment

A semiconductor device according to a second embodiment is different from the semiconductor device according to the first embodiment in that a second center position of a second trench in a first direction is not shifted in the first direction with respect to a first center position of a first trench in the first direction. Hereinafter, some of the content overlapping with that in the first embodiment will not be described in some cases.

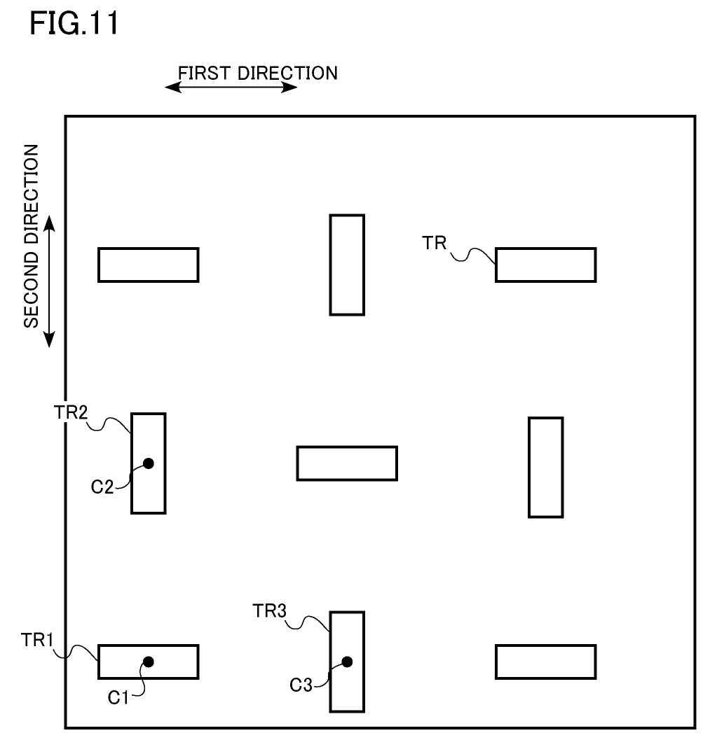

FIG. 11 is an enlarged schematic top view of the semiconductor device according to the second embodiment. FIG. 11 is a view corresponding to FIG. 2 of the first embodiment.

A second center position (C2 in FIG. 11) of the second trench TR2 in the first direction is not shifted in the first direction with respect to a first center position (C1 in FIG. 11) of the first trench TR1 in the first direction. In addition, a third center position (C3 in FIG. 11) of the third trench TR3 in the second direction is not shifted in the second direction with respect to the first center position (C1 in FIG. 11) of the first trench TR1 in the second direction.

As described above, according to the second embodiment, it is possible to achieve the semiconductor device capable of suppressing warpage of the semiconductor wafer as in the first embodiment.

### Third Embodiment

A semiconductor device according to a third embodiment is different from the semiconductor device according to the first embodiment in that a third direction intersects a second direction. Hereinafter, some of the content overlapping with that in the first embodiment will not be described in some cases.

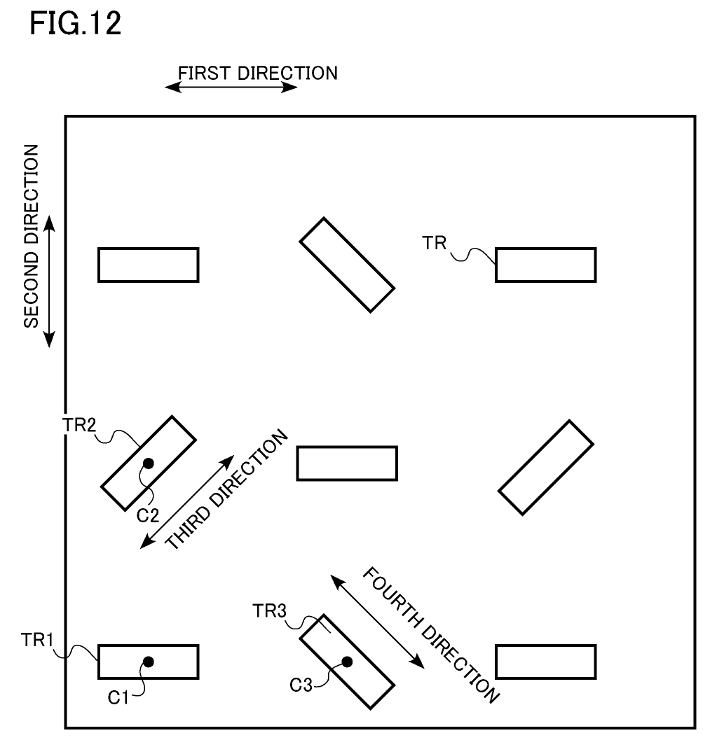

FIG. 12 is an enlarged schematic top view of the semiconductor device according to the third embodiment. FIG. 12 is a view corresponding to FIG. 2 of the first embodiment.

The second trench TR2 extends in the third direction intersecting a first direction and the second direction. In addition, the third trench TR3 extends in a fourth direction intersecting the first direction, the second direction, and the third direction.

As described above, according to the third embodiment, it is possible to achieve the semiconductor device capable of suppressing warpage of the semiconductor wafer as in the first embodiment.

Although a case where the semiconductor layer is silicon has been described as an example in the first to third embodiments, the semiconductor layer is not limited to silicon, and may be another semiconductor such as silicon carbide or a nitride semiconductor.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
an element region; and
a peripheral region surrounding the element region,
wherein the element region and the peripheral region include a semiconductor layer having a first face parallel to a first direction and a second direction, the second direction being orthogonal to the first direction, and a second face opposite to the first face,
the semiconductor layer in the peripheral region includes a plurality of trenches regularly disposed on the first face, and
the trenches include a first trench having a first major axis and a first minor axis and extending in the first direction, and a second trench adjacent to the first trench in the second direction, the second trench having a second major axis and a second minor axis and extending in a third direction parallel to the first face, the third direction intersecting the first direction.

2. The semiconductor device according to claim 1, wherein the third direction coincides with the second direction.

3. The semiconductor device according to claim 1, wherein the third direction intersects the second direction.

4. The semiconductor device according to claim 1, wherein the second major axis and the first major axis are equal, and the second minor axis and the first minor axis are equal.

5. The semiconductor device according to claim 1, wherein a second center position of the second trench in the first direction is shifted in the first direction with respect to a first center position of the first trench in the first direction.

6. The semiconductor device according to claim 1, wherein the trenches further include a third trench adjacent to the first trench in the first direction, the third trench having a third major axis and a third minor axis and extending in a fourth direction parallel to the first face, the fourth direction intersecting the first direction.

7. The semiconductor device according to claim 6, wherein the fourth direction coincides with the second direction.

8. The semiconductor device according to claim 6, wherein the fourth direction intersects the second direction.

9. The semiconductor device according to claim 6, wherein the third major axis and the first major axis are equal, and the third minor axis and the first minor axis are equal.

10. The semiconductor device according to claim 6, wherein a third center position of the third trench in the second direction is shifted in the second direction with respect to a first center position of the first trench in the second direction.

11. The semiconductor device according to claim 1, wherein the peripheral region further includes a first substance filling an inside of each of the trenches.

12. The semiconductor device according to claim 11, wherein the first substance includes an insulator.

13. The semiconductor device according to claim 11, wherein the first substance includes silicon oxide, silicon nitride, or polycrystalline silicon.

14. The semiconductor device according to claim 1, wherein a depth of the first trench is equal to or more than 5 times the first minor axis.

15. The semiconductor device according to claim 1, wherein the trenches are dummy patterns.
